(19) United States
(12) Patent Application Publication
(10) Pub. No.: US 2017/0343618 A1
(43) Pub. Date: Nov. 30, 2017

(54) LAYERED RF COIL FOR MAGNETOMETER

(71) Applicant: Lockheed Martin Corporation, Bethesda, MD (US)

(72) Inventors: Joseph W. Hahn, Erial, NJ (US); Duc Huynh, Princeton Junction, NJ (US)

(73) Assignee: Lockheed Martin Corporation, Bethesda, MD (US)

(21) Appl. No.: 15/380,691

(22) Filed: Dec. 15, 2016

Related U.S. Application Data
(60) Provisional application No. 62/343,492, filed on May 31, 2016.

(51) Int. Cl. G01R 33/032; G01R 33/00

(52) U.S. Cl. CPC G01R 33/032; G01R 33/0023

(57) ABSTRACT

A system for magnetic detection includes a magneto-optical defect center material comprising a plurality of magneto-optical defect centers, an optical light source, an optical detector and a radio frequency (RF) excitation source. The optical light source is configured to provide optical excitation to the magneto-optical defect center material. The optical detector is configured to receive an optical signal emitted by the magneto-optical defect center material, The RF excitation source is configured to provide RF excitation to the magneto-optical defect center material. The RF excitation source includes an RF feed connector, and a plurality of coils, each connected to the RF feed connector, and adjacent the magneto-optical defect center material, the coils each having a spiral shape.

### CROSS-REFERENCE TO RELATED PATENT APPLICATIONS

The present application claims the benefit of priority from U.S. Provisional Patent Application No. 62/343,492, filed May 31, 2016, which is incorporated herein by reference in its entirety.

### FIELD

The present disclosure generally relates to magnetic detection systems, and more particularly, to measurement and signal processing methods for a magnetic detection system.

### BACKGROUND

Many advanced magnetic imaging systems can operate in limited conditions, for example, high vacuum and/or cryogenic temperatures, which can make them inapplicable for imaging applications that require ambient conditions. Furthermore, small size, weight and power (SWAP) magnetic sensors of moderate sensitivity, vector accuracy, and bandwidth are valuable in many applications.

Atomic-sized nitrogen-vacancy (NV) centers in diamond have excellent sensitivity for magnetic field measurement and enable fabrication of small magnetic sensors that can readily replace existing-technology (e.g., Hall-effect) systems and devices. The sensing capabilities of diamond NV (DNV) sensors are maintained at room temperature and atmospheric pressure, and these sensors can be even used in liquid environments (e.g., for biological imaging). DNV sensing allows measurement of 3-D vector magnetic fields that is beneficial across a very broad range of applications.

### SUMMARY

According to certain embodiments, a system for magnetic detection may include: a magneto-optical defect center material comprising a plurality of magneto-optical defect centers; an optical light source configured to provide optical excitation to the magneto-optical defect center material; an optical detector configured to receive an optical signal emitted by the magneto-optical defect center material; and a radio frequency (RF) excitation source configured to provide RF excitation to the magneto-optical defect center material. The RF excitation source includes: an RF feed connector; and a plurality of coils, each connected to the RF feed connector, and adjacent the magneto-optical defect center material, the coils each having a spiral shape.

According to certain embodiments, a system for magnetic detection may include: a magneto-optical defect center material comprising a plurality of magneto-optical defect centers; an optical light source configured to provide optical excitation to the magneto-optical defect center material; an optical detector configured to receive an optical signal emitted by the magneto-optical defect center material; and a radio frequency (RF) excitation source configured to provide RF excitation to the magneto-optical defect center material. The RF excitation source may include: an RF feed connector; and a plurality of coils, each connected to the RF feed connector, and adjacent the magneto-optical defect center material, the coils arranged in layers one above another and to have a uniform spacing between each other. According to certain embodiments the coils may each have a spiral shape.

### BRIEF DESCRIPTION OF THE DRAWINGS

FIG. 1 illustrates one orientation of an NV center in a diamond lattice.

FIG. 2 illustrates an energy level diagram showing energy levels of spin states for the NV center.

FIG. 3 is a schematic diagram illustrating a NV center magnetic sensor system.

FIG. 4 is a graph illustrating the fluorescence as a function of an applied RF frequency of an NV center along a given direction for a zero magnetic field, and also for a non-zero magnetic field having a component along the NV axis.

FIG. 5 is a graph illustrating the fluorescence as a function of an applied RF frequency for four different NV center orientations for a non-zero magnetic field.

FIG. 6 is a schematic diagram illustrating a magnetic field detection system according to some embodiments.

FIG. 7 is a perspective view of a RF excitation source with a plurality of coils according to some embodiments.

FIG. 8A is a side view of the coils and a RF feed connector of the RF excitation source of FIG. 7.

FIG. 8B is a top view of the coils and a RF feed connector of the RF excitation source of FIG. 7.

FIG. 9A is a graph illustrating the magnetic field generated by the RF excitation source at 2 GHz in the region of the NV diamond material for a five spiral shaped coil arrangement.

FIG. 9B is a graph illustrating the magnetic field generated by the RF excitation source at 3 GHz in the region of the NV diamond material for the five spiral shaped coil arrangement.

FIG. 9C is a graph illustrating the magnetic field generated by the RF excitation source at 4 GHz in the region of the NV diamond material for the five spiral shaped coil arrangement.

FIG. 10 is a table illustrating the electric field and magnetic field generated by the RF excitation source in a region of the NV diamond material 620 at frequencies from 2.0 to 4.0 GHz for the five layer coil arrangement with spiral shaped coils.

### DETAILED DESCRIPTION

### The NV Center, its Electronic Structure, and Optical and RF Interaction

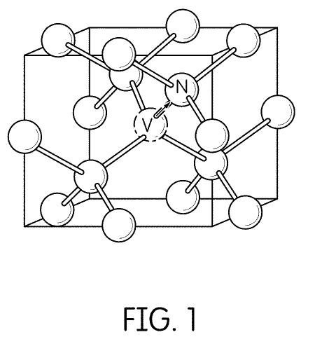

The NV center in a diamond comprises a substitutional nitrogen atom in a lattice site adjacent a carbon vacancy as shown in FIG. 1. The NV center may have four orientations, each corresponding to a different crystallographic orientation of the diamond lattice.

The NV center may exist in a neutral charge state or a negative charge state. The neutral charge state uses the nomenclature NV⁰, while the negative charge state uses the nomenclature NV, which is adopted in this description.

The NV center has a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

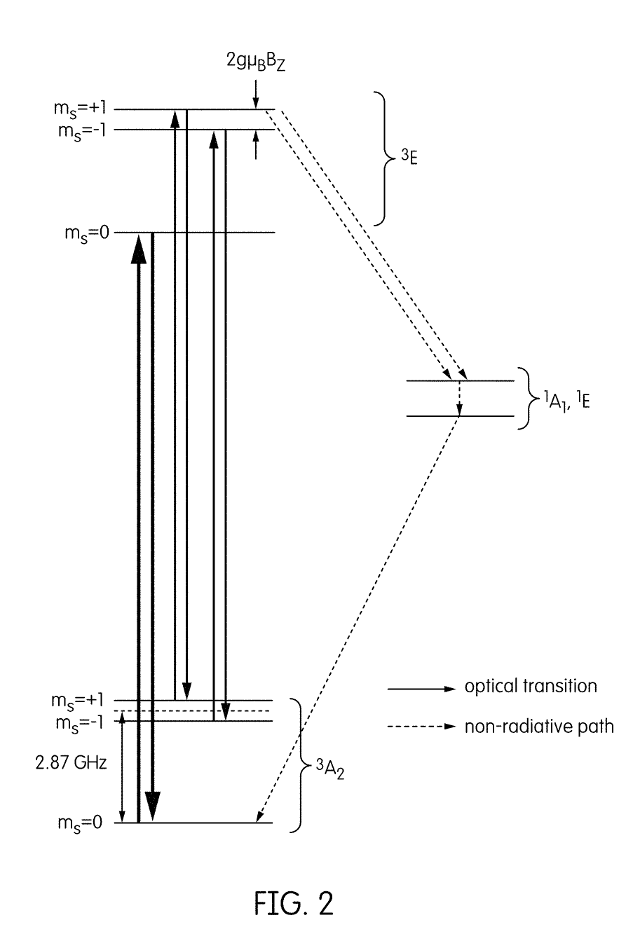

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of approximately 2.87 GHz for a zero external magnetic field.

Introducing an external magnetic field with a component along the NV axis lifts the degeneracy of the mₛ=±1 energy levels, splitting the energy levels mₛ=±1 by an amount 2 gμ_{B}Bz, where g is the g-factor, μ_{B} is the Bohr magneton, and Bz is the component of the external magnetic field along the NV axis. This relationship is correct to a first order and inclusion of higher order corrections is a straightforward matter and will not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light is emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

### The NV Center, or Magneto-Optical Defect Center, Magnetic Sensor System

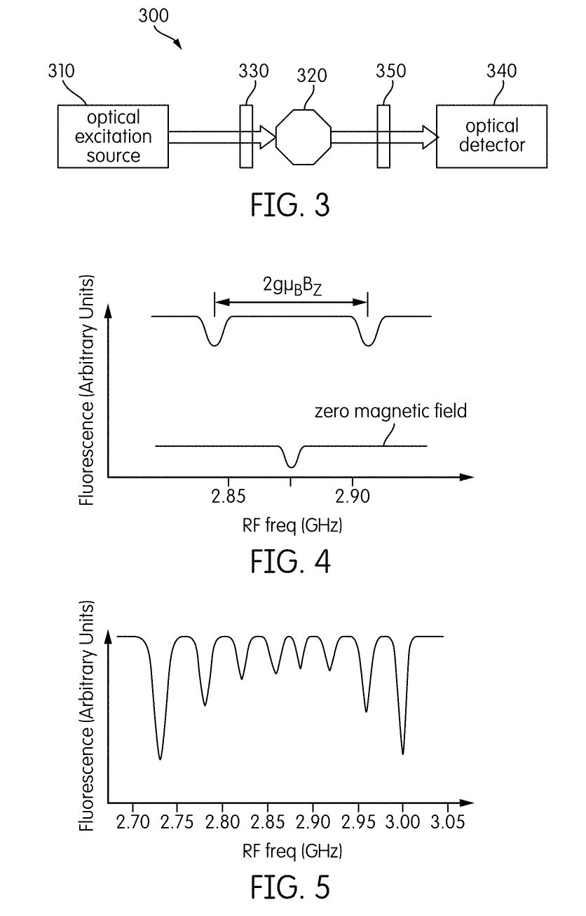

FIG. 3 is a schematic diagram illustrating a NV center magnetic sensor system 300 that uses fluorescence intensity to distinguish the mₛ=±1 states, and to measure the magnetic field based on the energy difference between the mₛ=+1 state and the mₛ=−1 state, as manifested by the RF frequencies corresponding to each state. The system 300 includes an optical excitation source 310, which directs optical excitation to an NV diamond material 320 with NV centers. The system further includes an RF excitation source 330, which provides RF radiation to the NV diamond material 320. Light from the NV diamond may be directed through an optical filter 350 to an optical detector 340.

The RF excitation source 330 may be a microwave coil, for example. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance and a subsequent decrease in fluorescence intensity occurs between the mₛ=0 spin state and the mₛ=−1 spin state of the ground state when the photon energy of the RF radiation emitted by the RF excitation source is the difference in energies of the mₛ=0 spin state and the mₛ=−1 spin state.

The optical excitation source 310 may be a laser or a light emitting diode, for example, which emits light in the green (light having a wavelength such that the color is green), for example. The optical excitation source 310 induces fluorescence in the red, which corresponds to an electronic transition from the excited state to the ground state. Light from the NV diamond material 320 is directed through the optical filter 350 to filter out light in the excitation band (in the green, for example), and to pass light in the red fluorescence band, which in turn is detected by the detector 340. The optical excitation light source 310, in addition to exciting fluorescence in the diamond material 320, also serves to reset the population of the mₛ=0 spin state of the ground state ³A₂ to a maximum polarization, or other desired polarization.

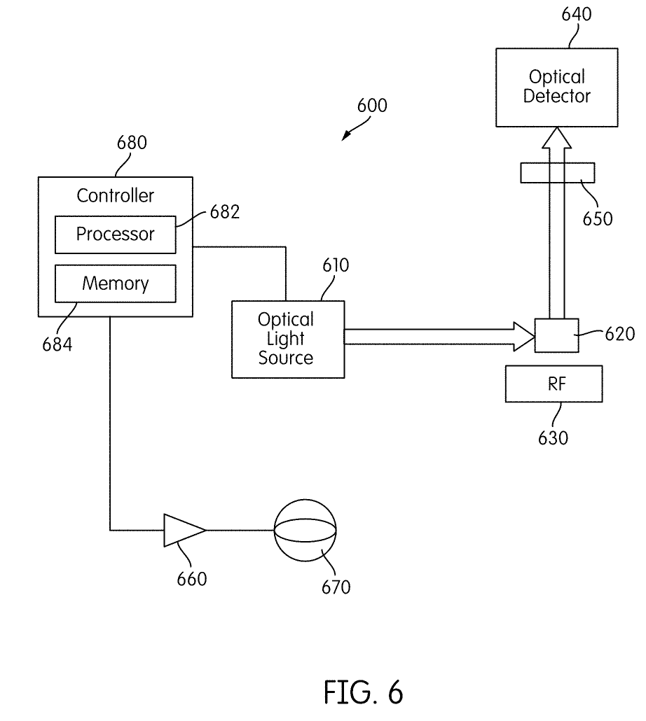

For continuous wave excitation, the optical excitation source 310 continuously pumps the NV centers, and the RF excitation source 330 sweeps across a frequency range that includes the zero splitting (when the mₛ=±1 spin states have the same energy) photon energy of approximately 2.87 GHz. The fluorescence for an RF sweep corresponding to a diamond material 320 with NV centers aligned along a single direction is shown in FIG. 4 for different magnetic field components Bz along the NV axis, where the energy splitting between the mₛ=−1 spin state and the mₛ=+1 spin state increases with Bz. Thus, the component Bz may be determined. Optical excitation schemes other than continuous wave excitation are contemplated, such as excitation schemes involving pulsed optical excitation, and pulsed RF excitation. Examples of pulsed excitation schemes include Ramsey pulse sequence (described in more detail below), and spin echo pulse sequence.

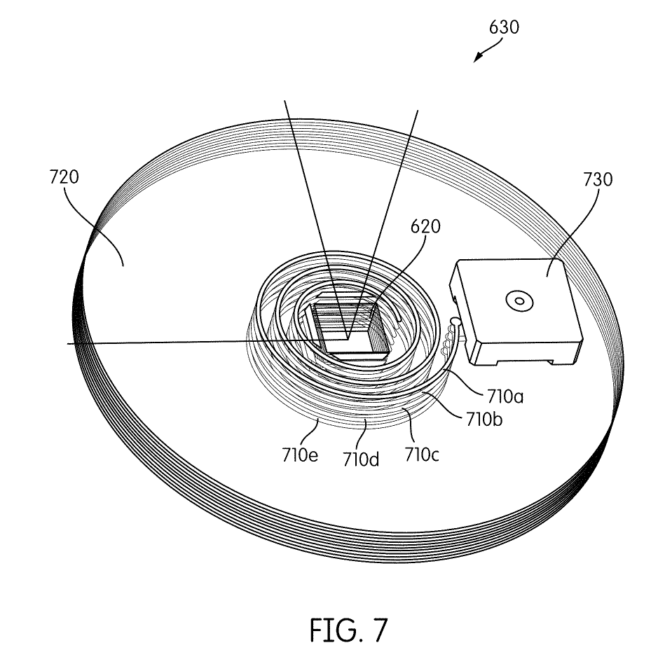

In general, the diamond material 320 will have NV centers aligned along directions of four different orientation classes. FIG. 5 illustrates fluorescence as a function of RF frequency for the case where the diamond material 320 has NV centers aligned along directions of four different orientation classes. In this case, the component Bz along each of the different orientations may be determined. These results, along with the known orientation of crystallographic planes of a diamond lattice, allow not only the magnitude of the external magnetic field to be determined, but also the direction of the magnetic field.

While FIG. 3 illustrates an NV center magnetic sensor system 300 with NV diamond material 320 with a plurality of NV centers, in general, the magnetic sensor system may instead employ a different magneto-optical defect center material, with a plurality of magneto-optical defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with NV diamond material.

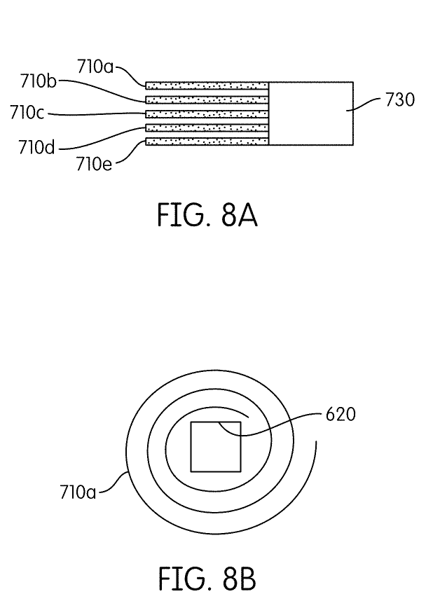

FIG. 6 is a schematic diagram of a system 600 for a magnetic field detection system according to some embodiments.

The system 600 includes an optical light source 610, which directs optical light to an NV diamond material 620 with NV centers, or another magneto-optical defect center material with magneto-optical defect centers. An RF excitation source 630 provides RF radiation to the NV diamond material 620. The system 600 may include a magnetic field generator 670 which generates a magnetic field, which may be detected at the NV diamond material 620, or the magnetic field generator 670 may be external to the system 600. The magnetic field generator 670 may provide a biasing magnetic field.

The system 600 further includes a controller 680 arranged to receive a light detection signal from the optical detector 640 and to control the optical light source 610, the RF excitation source 630, and the magnetic field generator 670. The controller may be a single controller, or multiple controllers. For a controller including multiple controllers, each of the controllers may perform different functions, such as controlling different components of the system 600. The magnetic field generator 670 may be controlled by the controller 680 via an amplifier 660, for example.

The RF excitation source 630 may include a microwave coil or coils, for example. The RF excitation source 630 may be controlled to emit RF radiation with a photon energy resonant with the transition energy between the ground mₛ=0 spin state and the mₛ=±1 spin states as discussed above with respect to FIG. 3, or to emit RF radiation at other nonresonant photon energies.

The controller 680 is arranged to receive a light detection signal from the optical detector 640 and to control the optical light source 610, the RF excitation source 630, and the magnetic field generator 670. The controller 680 may include a processor 682 and a memory 684, in order to control the operation of the optical light source 610, the RF excitation source 630, and the magnetic field generator 670. The memory 684, which may include a nontransitory computer readable medium, may store instructions to allow the operation of the optical light source 610, the RF excitation source 630, and the magnetic field generator 670 to be controlled. That is, the controller 680 may be programmed to provide control.

RF Excitation Source Coils

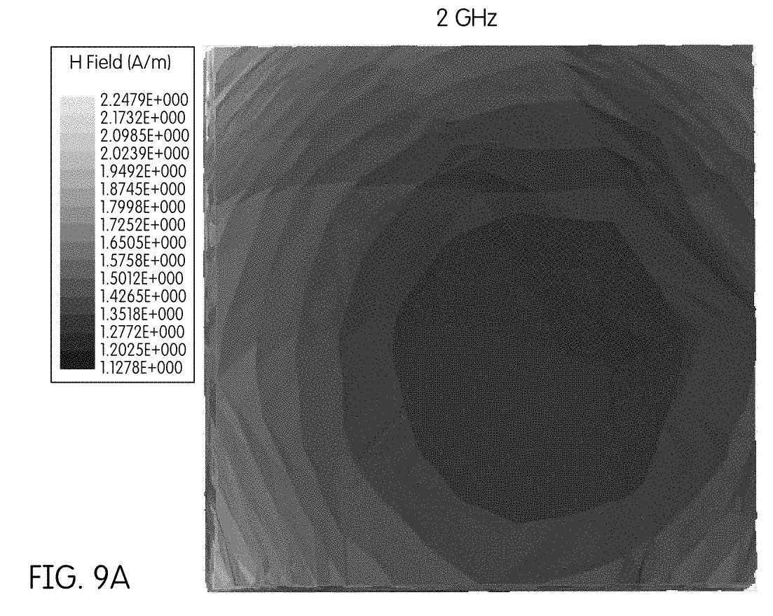

FIG. 7. illustrates the RF excitation source 630 with an arrangement of coils 710 and an NV diamond material 620. The RF excitation source 630 includes a plurality of coils 710a, 710b, 710c, 710d and 710e which may be arranged around the NV diamond material 620, where the coils 710 are in a layered arrangement one above the other. While the number of coils shown in FIG. 7 is five, the number may be more or less than five. The coils 710 may be formed in a substrate 720. The coils 710 may be connected to an RF feed connector 730 to allow power to be provided to the coils. The coils 710 may be connected in parallel to the RF feed connector 730.

While FIG. 7 illustrates the coils 710 to be arranged around the NV diamond material 620, the NV diamond material 620 may have other arrangements relative to the coils 710. For example, the NV diamond material 620 may be arranged above or below the coils 710. The NV diamond material 620 may be arranged normal to the coils 710, or at some other angle relative to the coils 710.

The substrate 720 may be a printed circuit board (PCB), for example, and the coils 710 may be layered in the PCB and separated from each other by dielectric material. The coils 710 may be formed of a conducting material such as a metal, such as copper, for example.

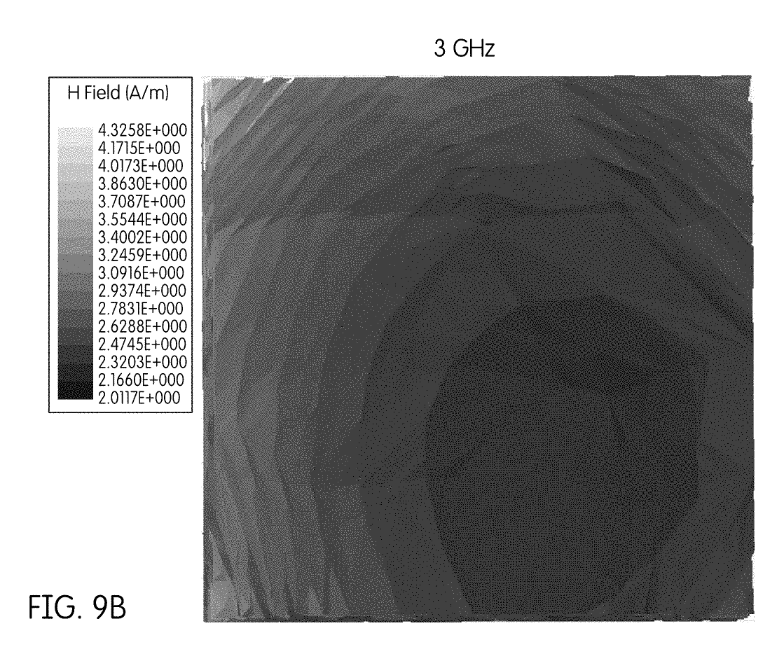

FIG. 8A is a side view of the coils 710 and the RF connector 730. The coils 710 are spaced from each other in the layered arrangement, and may be spaced by a uniform spacing. The coils may have any shape, such as square or spiral. Preferably, the coils may have a spiral shape, as shown in FIG. 7 and in FIG. 8B, which is a top view of the coils 710 and the RF connector 730. In FIG. 8B, only the top coil 710a can be seen, because the coils 710b, 710c, 710d and 710e are below the top coil 710b.

The uniform spacing of the coils 710 and uniform spacing between the spiral shape coils allow the RF excitation source 630 to provide a uniform RF field in the NV diamond material 620 over the frequency range needed for magnetic measurement of the NV diamond material 620, which may enclosed by the coils 7. This arrangement provides both uniformity in phase and gain of the RF signal throughout the needed frequency range, and throughout the different regions of the NV diamond material 620. Further, the layered coils may be operated in a pulsed manner and in this arrangement in order to avoid unnecessary overlap interference. The interference is reduced in pulsed operation of the coils 710.

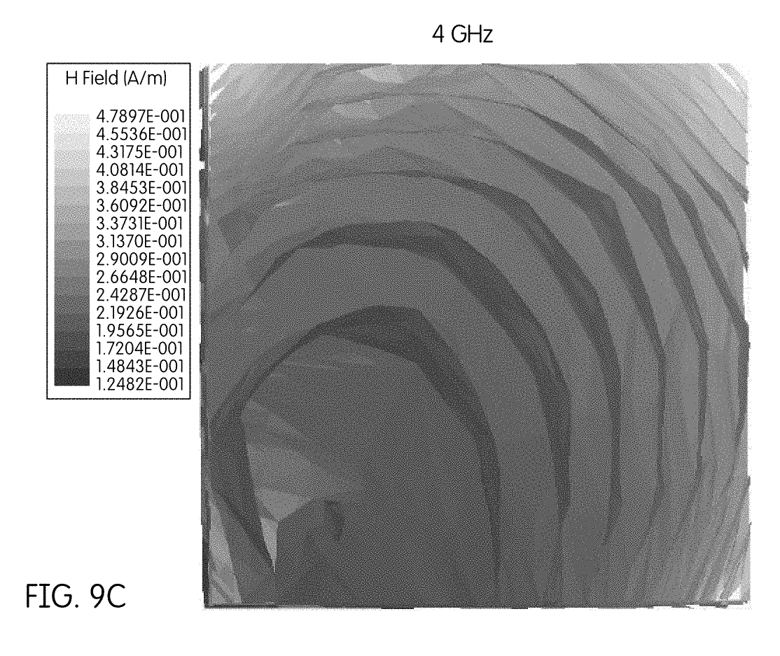

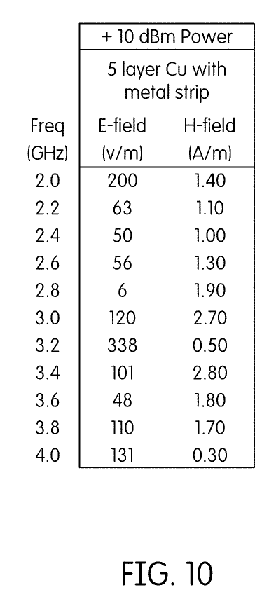

FIGS. 9A, 9B and 9C illustrate the magnetic field H generated by the RF excitation source 630 in a plane parallel to the plane of the coils 710 in the region of the NV diamond material 620 at frequencies of 2 GHz, 3 GHz and 4 GHz, respectively. The arrangement is for a five layer coil with spiral shaped coils. FIG. 10 is a table illustrating the electric field E and magnetic field H generated by the RF excitation source 630 in the region of the NV diamond material 620 at frequencies from 2.0 to 4.0 GHz for the five layer coil arrangement with spiral shaped coils. Thus, FIGS. 9A, 9B and 9C illustrate the uniformity of the magnetic field, and FIG. 10 illustrates the uniformity of the electric field E and magnetic field H in the NV diamond material 620 over the needed frequency range, and throughout the different regions of the NV diamond material 620.

The embodiments of the inventive concepts disclosed herein have been described in detail with particular reference to preferred embodiments thereof, but it will be understood by those skilled in the art that variations and modifications can be effected within the spirit and scope of the inventive concepts.

What is claimed is:

1. A system for magnetic detection, comprising:
a magneto-optical defect center material comprising a plurality of magneto-optical defect centers;
an optical light source configured to provide optical excitation to the magneto-optical defect center material;
an optical detector configured to receive an optical signal emitted by the magneto-optical defect center material; and
a radio frequency (RF) excitation source configured to provide RF excitation to the magneto-optical defect center material, the RF excitation source comprising:
an RF feed connector; and
a plurality of coils, each connected to the RF feed connector, and adjacent the magneto-optical defect center material, the coils each having a spiral shape.

2. The system for magnetic detection of claim 1, wherein the coils are arranged in layers one above another.

3. A system for magnetic detection, comprising:
a magneto-optical defect center material comprising a plurality of magneto-optical defect centers;
an optical light source configured to provide optical excitation to the magneto-optical defect center material;
an optical detector configured to receive an optical signal emitted by the magneto-optical defect center material; and
a radio frequency (RF) excitation source configured to provide RF excitation to the magneto-optical defect center material, the RF excitation source comprising:
an RF feed connector; and
a plurality of coils, each connected to the RF feed connector, and adjacent the magneto-optical defect center material, the coils arranged in layers one above another and to have a uniform spacing between each other.

4. The system for magnetic detection of claim 3, wherein the coils each have a spiral shape.
